(19) United States
(12) Patent Application Publication
(10) Pub. No.: US 2009/0187801 A1
(43) Pub. Date: Jul. 23, 2009

(54) METHOD AND SYSTEM TO PERFORM AT-SPEED TESTING

(76) Inventor: Kamlesh Pandey, Bangalore (IN)

Correspondence Address: MCANDREWS HELD & MALLOY, LTD, 500 WEST MADISON STREET, SUITE 3400, CHICAGO, IL, 60661, US

(21) Appl. No.: 12/016,044

(22) Filed: Jan. 17, 2008

(51) Int. Cl. G01R 31/28

(52) U.S. Cl. 714/729

(57) ABSTRACT

Herein described are at least a method and a system to perform at-speed scan testing of a digital integrated circuit chip. The digital integrated circuit chip is segmented into a plurality of segments wherein each segment comprises a signal conditioning circuitry. In a representative embodiment, the signal conditioning circuitry conditions and/or regenerates a scan enable control signal used to select either a scan-shift or capture mode during scan testing of the digital integrated circuit chip. In a representative embodiment, the method comprises dividing a scan chain into multiple segments and positioning a conditioning circuitry within each of the segments.

### CROSS-REFERENCE TO RELATED APPLICATIONS/INCORPORATION BY REFERENCE

[Not Applicable]

### FEDERALLY SPONSORED RESEARCH OR DEVELOPMENT

[Not Applicable]

### MICROFICHE/COPYRIGHT REFERENCE

[Not Applicable]

### BACKGROUND OF THE INVENTION

In the testing digital integrated circuit chips, it is important to be able to test the operation of one or more scan chains. As the operational frequency of the digital integrated circuit increases, and as the size of a scan chain increases with sub-micron fabrication technologies, it is important to perform adequate testing to identify defects and assure acceptable production yields.

The limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

Various aspects of the invention can be found in a method and a system of performing “at-speed” scan testing of an integrated circuit chip. The various aspects and representative embodiments of the method and system are substantially shown in and/or described in connection with at least one of the following figures, as set forth more completely in the claims.

These and other advantages, aspects, and novel features of the present invention, as well as details of illustrated embodiments, thereof, will be more fully understood from the following description and drawings.

### BRIEF DESCRIPTION OF THE DRAWINGS

FIG. 1 is a block diagram representation of an at-speed scan architecture (ASSA), in accordance with an embodiment of the invention.

FIG. 2A is a detailed logic diagram of the clock generation circuitry shown in FIG. 1, in accordance with an embodiment of the invention.

FIGS. 2B and 2C are timing diagrams illustrating the operation of the detailed logic diagram provided in FIG. 2A, in accordance with an embodiment of the invention.

FIG. 3 is a detailed logic diagram of a circuitry used to condition and regenerate a control signal for selecting a scan-in (or scan-shift) mode or a capture mode of operation during scan testing, in accordance with an embodiment of the invention.

FIG. 4 is a detailed logic diagram of a lock logic control circuitry used to generate a lock logic control signal, in accordance with an embodiment of the invention.

FIG. 5 is a detailed logic diagram of a lock logic circuitry for properly transmitting data from a first segment in a first clock domain to a second segment of a second clock domain, in accordance with an embodiment of the invention.

FIG. 6 is an operational flow diagram describing the process of implementing at-speed scan testing of one or more scan chains, in accordance with an embodiment of the invention.

### DETAILED DESCRIPTION OF THE INVENTION

In very deep sub-micron (VDSM) IC fabrication technologies, defects may occur that are not caught by traditional forms of testing such as stuck-at-fault testing, for example. These defects may comprise high impedance metal, high impedance shorts, and cross-talk defects, for example. These defects may be identified and isolated using “at-speed” testing, which tests a digital integrated circuit at its intended operational frequencies. Often, the operational frequencies are generated by the digital integrated circuit's system clock. The digital integrated circuit chip may comprise a plurality of scan chains. Each scan chain may comprise a plurality of flip-flops. In accordance with the various aspects of the invention, the scan testing may be performed using one or more scan clocks. Externally, one or more scan clocks may be generated externally or internally from within the digital integrated circuit chip. The external one or more scan clocks may be generated by an automatic test pattern generator (ATPG) or an automatic test equipment (ATE), for example. One or more scan clocks may be supplied to the integrated circuit chip by way of using a single pin on the integrated circuit chip. The one or more scan clocks may have clock frequencies adequate for scanning in scan test vectors associated with the scan testing of the digital integrated circuit chip. The scan clock frequencies used for scanning in the test vectors may be lower in frequency than one or more scan clocks used for performing at-speed scan testing. The one or more scan clocks used for performing at-speed scan testing may originate from within the digital integrated circuit chip. The one or more scan clocks used for performing at-speed scan testing may originate from a phase locked loop (PLL), for example. The various aspects of the present invention may be applied to sub-micron integrated circuit fabrication process technologies, such as a 90 nanometer (nm) fabrication process.

When scan testing is performed, one or more control signals may be used to select one or more modes (or phases) of operation. The one or more control signals may comprise a scan enable control signal used for controlling and operating the scan testing of a digital integrated circuit in either a scan-in (scan-shift) mode or a capture mode, for example. As used herein, “scan-in” may be alternatively referred to or described as “scan-shift”, and vice-versa. The scan-in (or scan-shift) mode allows shifting in of a test vector into a scan-in (SI) or test-in (TI) input of a flip-flop of a scan chain or segment. The capture mode allows functional testing of circuitry associated with the data (D) input of the flip-flop of the scan chain or segment. If the electrical properties of the scan enable control signal are affected, operation in either the scan-in mode or capture mode may be significantly affected. As a consequence, scan testing may be affected, for example, while performing at-speed testing during capture mode since the operational clock frequencies are higher in this capture mode. The electrical properties or characteristics of a scan enable control signal may be affected by the loading that results from driving an excessive number of flip-flops in a scan chain, for example. This may have a profound effect when performing at-speed testing in the capture mode.

Various aspects of the invention can be found in a method and a system of performing “at-speed” scan testing of an integrated circuit chip by way of segmenting each of one or more scan chains into multiple segments. Each of the segments comprises a portion of a scan chain of the one or more scan chains in the digital integrated circuit chip. Each segment comprises a subset of the total number of flip-flops in a scan chain. Various aspects of the invention incorporate a scan enable control signal regeneration circuitry in each of the resulting segments. By way of segmenting a scan chain and adding such scan enable control signal regeneration circuitry, the effect of current load caused by all flip-flops of a scan chain is reduced while the electrical characteristics of the scan enable control signal provided to each flip-flop is improved. The scan enable control signal regeneration circuitry may be used to regenerate and/or condition the scan enable signal for use by each of the one or more flip-flops in each of the resulting segments. Each segment comprises a portion, fraction, or subset of the flip-flops of a scan chain. For example, a scan chain that originally contained 100,000 flip-flops may be divided into 10 segments, in which each segment contains 10,000 flip-flops. A designer may suitably determine the maximum number of flip-flops contained in a segment. The number of flip-flops per segment may be determined based on the desired current load or fan out requirement per segment.

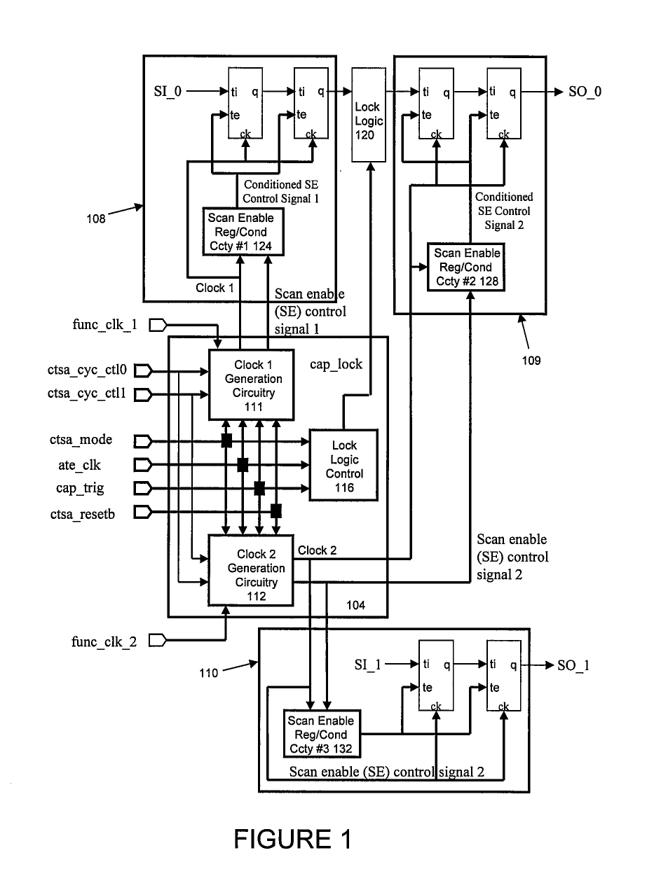

FIG. 1 is a block diagram representation of an at-speed scan architecture (ASSA) in accordance with an embodiment of the invention. The ASSA comprises a clock generation module 104 and a plurality of scan chain segments 108, 109, 110. The plurality of scan chain segments 108, 109, 110 may comprise segments originating from one or more scan chains. The clock generation module 104 receives a number of input signals. The clock generation module 104 comprises a first clock generation circuitry (i.e., clock 1 generation circuitry) 111, a second clock generation circuitry (i.e., clock 2 generation circuitry) 112, and a lock logic control circuitry 116, for example. Although the representative embodiment of FIG. 1 depicts the generation of two clocks using two clock generation circuitries 111, 112, the various aspects of the invention may be adapted for generating any number of clocks using any number of clock generation circuitries. The first clock generation circuitry 111 and the second clock generation circuitry 112 may receive functional clock signals (e.g., func_clk_1, func_clk_2) and one or more control signals, (e.g., ctsa_cyc_ctl0 and ctsa_cyc_ctl1), as illustrated in FIG. 1. Additional control signals may be provided to the first clock generation circuitry 111, the second clock generation circuitry 112, and the lock logic control circuitry 116. In the embodiment illustrated in FIG. 1, these signals are termed ctsa_mode, ate_clk, cap_trig, and ctsa_resetb, for example. The functional clock signals, func_clk_1 and func_clk_2, may originate from one or more phase locked loops (PLLs) within an integrated circuit chip, for example. In the representative embodiment shown in FIG. 1, the first clock generation circuitry 111 generates a first clock and a first scan enable (SE) control signal to the first segment 108, while the second clock generation circuitry 112 generates a second clock and a second scan enable (SE) control signal to each of two segments 109, 110. For each flip-flop in each segment, the test enable (te) or scan enable input receives a scan enable control signal. When a scan-in or scan-shift is performed the test-in (ti) or scan-in inputs are used for each flip flop in each segment. Scan enable regeneration/conditioning circuitries 124, 128, 132 are used to condition and regenerate received scan enable control signals (i.e., scan enable (SE) control signal 1 and scan enable (SE) control signal 2 provided by their respective clock generation circuitries 111, 112 in the clock generation module 104. In the representative embodiment illustrated in FIG. 1, the first segment 108 and second segment 109 operate in different clock domains; as a consequence the first segment 108 is clocked by the first clock while the second segment 109 is clocked by the second clock. Data from the first segment 108 operating in a first clock domain may be transmitted to the second segment 109 operating in a second domain. A lock logic circuitry 120 may be used to effectively transmit the data between the two different clock domains. Although not shown in FIG. 1, should a segment output into another segment having the same clock domain, the lock logic circuitry 120 may not be used. The lock logic circuitry 120 may be controlled and/or clocked by a signal transmitted from the clock generation module 104. A lock logic control circuitry 116 may be used to generate this signal. As illustrated, the lock logic control circuitry 116 generates a cap_lock signal to the lock logic circuitry 120. For simplicity, only two flip-flops are illustrated in each of the segments 108, 109, 110 of the at-speed scan architecture (ASSA) shown in FIG. 1, although each of the segments 108, 109, 110 may comprise any portion of flip-flops of the total number of flip-flops in its corresponding scan chain.

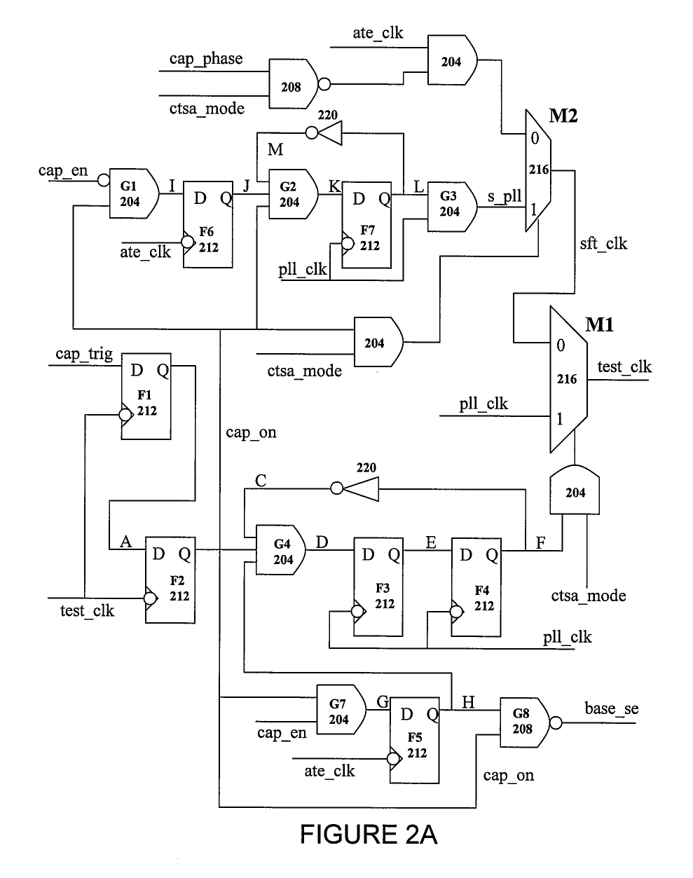

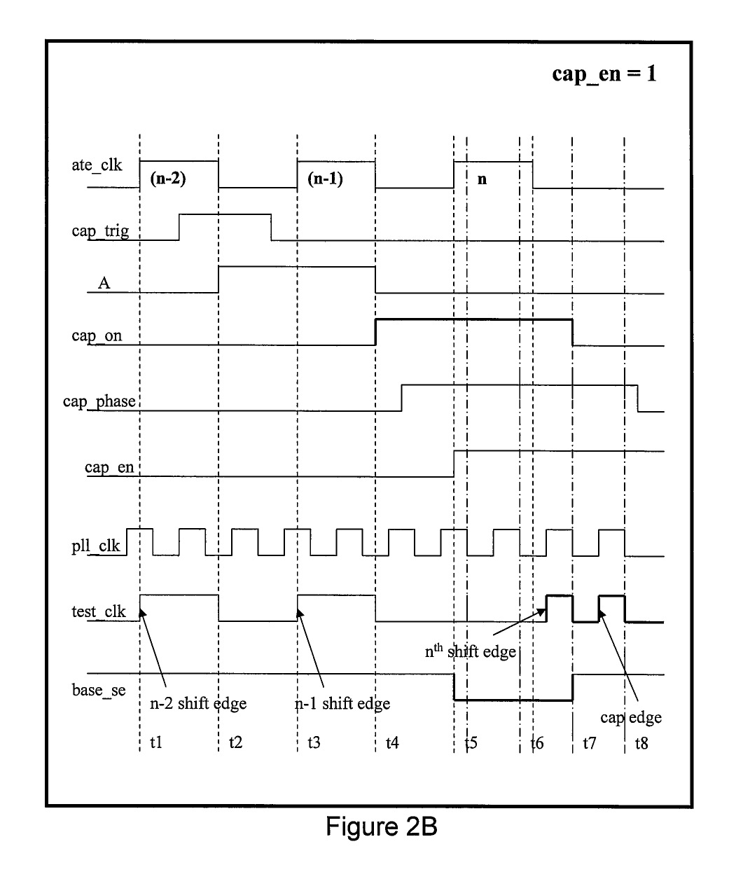

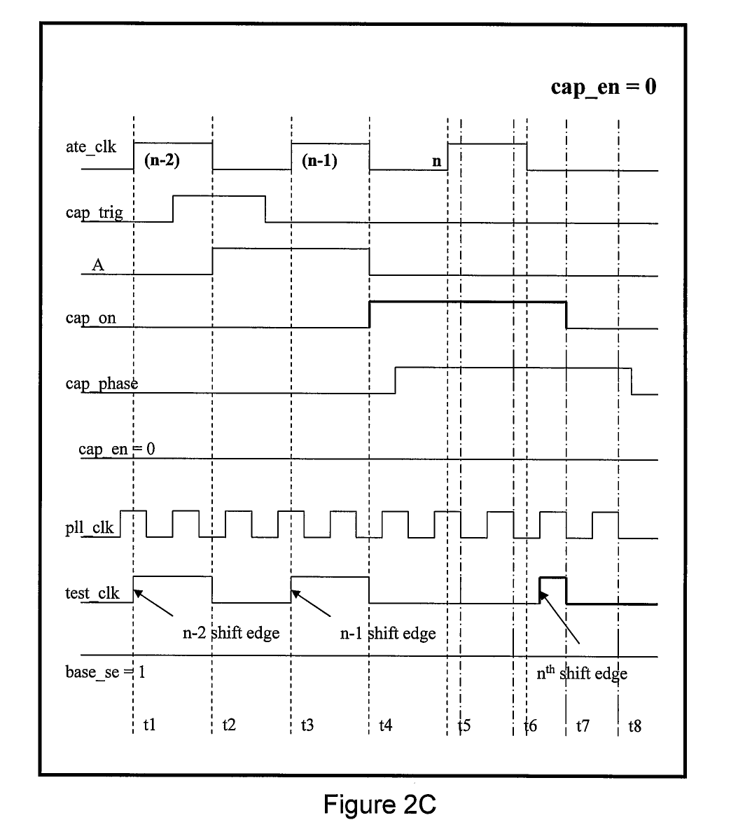

FIG. 2A is a detailed logic diagram of the clock generation circuitry corresponding to either element 111 (clock 1 generation circuitry) or 112 (clock 2 generation circuitry), as shown in FIG. 1, in accordance with an embodiment of the invention. The clock generation circuitry generates and transmits a clock signal (clk) and a scan enable (SE) control signal (base_se) to one or more of the previously described segments of one or more scan chains. The clock generation circuitry comprises digital logic circuitry. As illustrated the clock generation circuitry comprises a number of AND gates 204, NAND gates 208, flip-flops 212, multiplexers 216, and inverters 220.

The input signals illustrated in FIG. 2 may be described as follows:
ate_clk: The ate_clk signal may be supplied from an automatic test equipment (ATE), for example. The ate_clk may be input to the two clock generation circuitries previously described in reference to FIG. 1, for example. The ate_clk may be used to shift data during a scan-in or scan-shift mode when scan testing a scan chain.
pll_clk: The pll_clk signal may originate from an on-chip clock source such as a PLL or a clock divider, for example. The pll_clk signal is usually a high speed clock. The clock generation circuitries that were previously described in reference to FIG. 1 may use this clock to perform a last shift in a scan-in mode and/or to generate one or more capture pulses during a capture mode while scan testing a scan chain.
cap_trig: The cap_trig signal may be used to indicate the start of a capture mode or capture phase. This cap_trig input synchronizes the switching of the ate_clk signal to the pll_clk signal during a capture mode or capture phase.
cap_phase: When at a logical high level, the cap_phase signal functions to block the transmission of ate_clk to clk, during the last shift cycle and/or the capture cycle. The cap_phase signal may be used to disable all scan lockup latches within a lock logic circuitry of an at-speed scan architecture (ASSA) during capture mode or capture phase. In this way, each clock domain may be isolated from each other during a capture phase.
cap_en: The cap_en signal may be used to determine if a clock domain generates a capture pulse.
cap_on: The cap_on signal may be used to enable or control outputting of a clock signal (i.e., the test_clk signal in FIG. 2A) from the clock generation circuitry. A test_clk signal may be generated by a clock generation circuitry when cap_on enables transmission of the pll_clk. For example, a cap_on signal associated with the clock 1 generation circuitry described in connection with FIG. 1, may be used to enable transmission of the clock 1 signal to its associated scan chain segment. Likewise, a cap_on signal associated with the clock 2 generation circuitry described in connection with FIG. 1, may be used to enable transmission of its clock 2 signal to its associated scan chain segment.
ctsa_mode: The ctsa_mode signal determines whether the corresponding digital integrated circuit chip is in scan test mode.
test_clk: The test_clk signal may be used during scan-in (i.e., scan-shift) and capture modes. This output may be derived from ate_clk input and pll_clk signals. The test_clk signal may be fed back into the clock generation circuitry as a way to self-synchronize itself. For example, with regard to FIG. 1, the test_clk signal corresponding to the clock 1 generation circuitry is called Clock 1 while the test_clk signal corresponding to the clock 2 generation circuitry is called Clock 2.

The output signals of the clock generator circuitry comprise test_clk and base_se. The description of the output signals are following;
base_se: The base_se signal may be generated during the N−1 shift cycle. Here N is the total number of scan shifts required to load all flip-flops in a scan chain.

FIGS. 2B and 2C illustrate timing diagrams describing the operation of the clock generation circuitry when cap_en=1 and when cap_en=0, respectively. The clock generation circuitry provides two modes of operation: (1) capture enable mode, (i.e., when cap_en=1) and (2) capture disable mode, (i.e., when cap_en=0).

In capture enable mode (cap_en=1), the first step is to assert the ctsa_mode signal to HIGH and this signal will remain HIGH throughout the scan test. The second step is to reset all the flops shown in FIG. 2A at the beginning of the scan test. In the beginning of the scan test, H is LOW, enabling gate G1 to pass tester clock and F is LOW; hence mux M1 selects sft_clk as test_clk. The scan test uses n−3 cycles as usual. After (n−3)th cycles, the at-speed scan architecture asserts cap_trig signal to HIGH indicating the beginning of the capture process. Here n is equal to total number of shift cycles required to load scan chains fully. At time t2 (i.e., at the negative edge of the (n−2)th shift cycle), the flip-flop F1 captures data HIGH. The cap_trig signal is asserted LOW again before the negative edge of the (n−1)th shift, prior to the period corresponding to time t3. Flip-flop F2 captures data HIGH at the negative edge of the (n−1)th scan-in cycle (t4). Since the clock domain is selected for capturing data, point G (see FIG. 2A) goes HIGH in the (n−1)th cycle. After the (n−1)th negative edge (i.e., at t4), point H goes HIGH blocking tester clock from gate G1. At time t5, flip-flop F5 captures data HIGH on the rising edge of the nth tester shift cycle. At the same time, point D goes HIGH and in the next falling edge of pll_clk clock (i.e, at t5) flip-flop F3 captures data HIGH and point E goes HIGH. Subsequently, the falling edge (at time t6) of the pll_clk captures data HIGH into flip-flop F4 and then point F goes HIGH. Multiplexer M1 selects pll_clk as test_clk at the same time that point D goes LOW. In the next falling edge of pll_clk, point E (at time t7) goes LOW, and after one more cycle (i.e., at time t8), point F goes LOW. Thus, point F remains HIGH for two pll_clk pulses. This allows two pll_clk pulses to pass through multiplexer M1. The pll_clk signal pulse operates in the last shift (nth) cycle. The second pll_clk pulse acts as a capture pulse.

Capture disable mode (cap_en=0): In this mode, points H and I always remain LOW. This forces point D to remain LOW during a capture window. The gate G1 enables flip-flop F7 to generate the last shift-in pulse. Multiplexer M2 selects signal s_pll that is generated using pll_clk. Also base_se always remains HIGH since no capture is required.

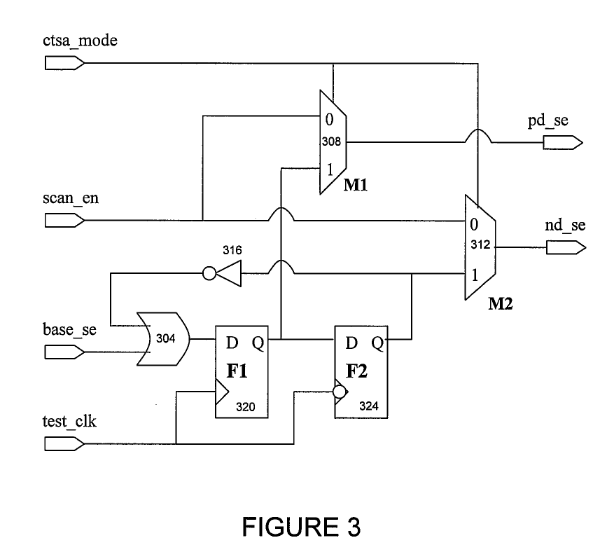

FIG. 3 is a detailed logic diagram of a circuitry used to condition and regenerate a control signal used for selecting a scan-in mode or a capture mode of operation during scan testing, in accordance with an embodiment of the invention. Hereinafter, the control signal may be alternatively described as a scan enable control signal. Hereinafter, the circuitry may be alternatively described as a scan enable regeneration circuitry. The scan enable regeneration circuitry comprises an OR gate 304, a first multiplexer 308, a second multiplexer 312, an inverter 316, a first flip-flop 320, and a second flip-flop 324. As shown, the scan enable regeneration circuitry receives exemplary input signals ctsa_mode, scan_en, base_se, and clk. When ctsa_mode is LOW, multiplexers 308, 312 select conventional scan enable signal (scan_en) in order to support conventional scan-in automatic test pattern generation (ATPG). The scan enable regeneration circuitry generates output signals pd_se and nd_se. The scan enable regeneration circuitry generates distribution or local scan enable signals that are connected to each flip-flop of a segment of a scan chain. As described earlier, a scan chain may be divided or segmented into multiple segments, such that each segment contains a scan enable regeneration circuitry. A first scan enable regeneration circuitry conditions and regenerates a first scan enable control signal provided by a first clock generation circuitry, such as the first clock generation circuitry previously discussed in reference to FIG. 1. Likewise, a second scan enable regeneration circuitry conditions and regenerates a second scan enable control signal provided by a second clock generation circuitry, such as the second clock generation circuitry previously discussed in reference to FIG. 1. The scan enable regeneration circuitry allows each and every flip-flop of each segment of a scan chain to be adequately driven by a scan enable control signal. The scan enable control signal is transmitted to the test enable (te) or scan enable input of a flip-flop. Output signal pd_se is generated in response to rising edge of test_clk while nd_se is generated with respect to falling edge of test_clk. The pd_se signal is connected to positive edge triggered flip-flops in a segment of a scan chain while the nd_se signal is connected to negative edge triggered flip-flops in a segment of a scan chain. By way of regenerating the scan enable control signal provided by the clock generation circuitries previously described in reference to FIG. 1, it is insured that a full functional clock cycle is available when distributing the scan enable signal to each segment. As a method to ease timing requirements, the scan enable conditioning circuitry 124, 128, 132 may be replicated multiple times using a plurality of segments for a single clock domain.

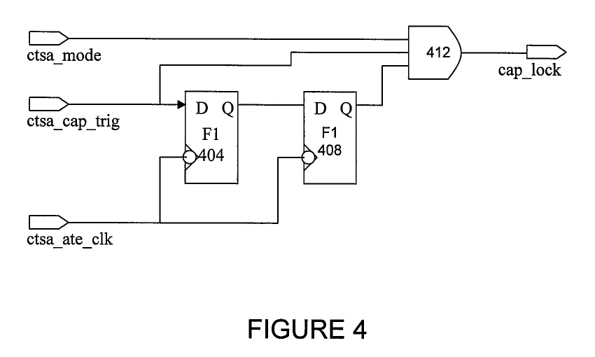

FIG. 4 is a detailed logic diagram of a lock logic control circuitry used to generate a lock logic control signal, in accordance with an embodiment of the invention. The lock logic control signal may be used to control the storage and transfer of the last data shifted in from the last flip-flop of a segment to a first flip-flop of a successive segment when two segments operate in different clock domains. The lock logic control circuitry generates a lock logic control signal (i.e., cap_lock) to the lock logic circuitry such that the data associated with the last data shift for a first scan segment in a first clock domain is transferred to the first flip-flop at the beginning of a next scan segment in a second clock domain. In the representative embodiment shown in FIG. 4, the lock logic control circuitry comprises a first flip-flop 404, a second flip-flop 408, and an AND gate 412. As shown, ctsa_mode, cap_trip, and ate_clk comprise inputs while cap_lock comprises an output to the lock logic control circuitry. Aspects of invention may not be so limited to the embodiments previously described, and it is contemplated that additional embodiments may be implemented using and/or incorporating other logic circuitry without departing from the scope of the invention.

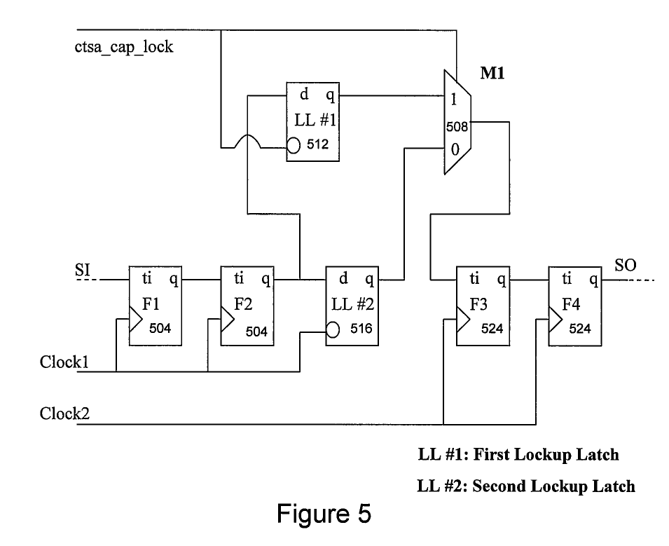

FIG. 5 is a detailed logic diagram of a lock logic circuitry for properly transmitting data from a first segment in a first clock domain to a second segment of a second clock domain, in accordance with an embodiment of the invention. The lock logic circuitry comprises a multiplexer 508, a first lockup latch 512, and a second lockup latch 516. Although illustrated in FIG. 5, flip-flops 504, 524 are not part of the lock logic circuitry. Flip-flops 504 correspond to the last two flip-flops of a first segment of a first clock domain while flip-flops 524 correspond to the first two flip-flops of a second segment of a second clock domain. The lock logic circuitry receives a lock logic control signal (i.e., cap_lock) from the previously described lock logic control circuitry shown in FIG. 4. The lock logic circuitry is used to reroute data transmission between two nodes during the last clock cycle of a scan-in mode and the first clock cycle of a capture mode. The lock logic circuitry functions to provide isolation between two clock domains after the last scan-in clock cycle (or period) of a scan-in or scan-shift mode, prior to entering the first cycle of a capture mode. The cap_lock signal remains at a logic low level until the last clock cycle of a scan-in or scan-shift mode. When cap_lock is at a logic low level, the second lockup latch 516 is used in the transmission of data from the first segment to the second segment. Prior to the last clock cycle of the scan-in mode, the first lockup latch is functionally transparent and acts as a buffer. During the last clock cycle of the scan-in mode, cap_lock goes to a logic high level and the multiplexer 520 selects the output of the first lockup latch 516 between flip-flop F2 504 and flip-flop F3 524.

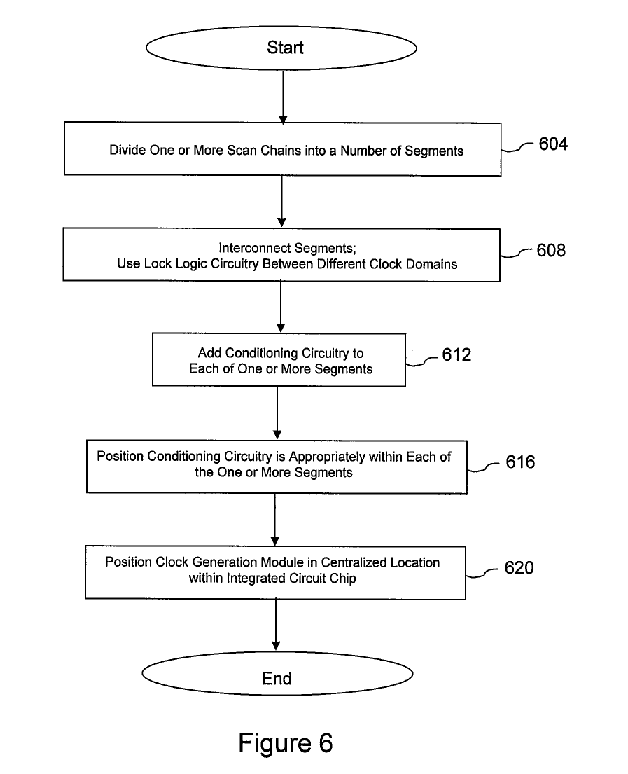

FIG. 6 is an operational flow diagram describing the process of implementing at-speed scan testing of one or more scan chains, in accordance with an embodiment of the invention. At step 604, the process comprises dividing one or more scan chains into a number of segments, wherein each of the segments comprises a subset of flip-flops of a scan chain of the one or more scan chains of a digital integrated circuit chip. Dividing the scan chains into a number of segments minimizes the loading that affects a control signal such as a scan enable signal. Loading, may result from current drain generated by each flip-flop of the scan chain of the one or more scan chains. Next, at step 608, the various segments are interconnected such that data may be transmitted from one segment to a successive segment during a scan-in or scan-shift mode. The interconnections may be made to regenerate the original data transmission path(s) of the one or more scan chains, before the scan chains are divided into segments. When interconnecting two segments that operate in different clock domains, a lock logic circuitry may be used to connect the segments. Next, at step 612, the process continues by adding conditioning circuitry to each of the number of segments, wherein the conditioning circuitry is used to condition a first control signal received by each of the segments. The circuitry regenerates a second control signal used by each of the flip-flops, wherein the conditioned second control signal is capable of driving each of the plurality of flip-flops with sufficient current even at high frequencies. The process continues at step 616, where the circuitry is positioned within each of the segments such that the second control signal is distributed to each of a plurality of conductive paths leading to the plurality of flip-flops such that the variation in lengths of the conductive paths is minimized. The second control signal comprises a conditioned and/or regenerated scan enable signal used to drive the test enable or scan enable inputs of the flip-flops in a segment, for example. A layout engineer may appropriately position the circuitry to minimize the variation in the path lengths between the circuitry and each of the one or more flip-flops in a segment. The engineer may position the circuitry such that the variation in path lengths is negligible or equal to zero. Finally, at step 620, the clock generation module, previously described in reference to FIG. 1, may be positioned in a centralized location on the digital integrated circuit chip, such that the variation of the conductive path lengths from the clock generation module to each of the segments is also minimized or set equal to zero. Therefore, the clock generation module may be positioned in a location that is equidistant to the segments in the integrated circuit chip.

While the invention has been described with reference to certain embodiments, it will be understood by those skilled in the art that various changes may be made and equivalents may be substituted without departing from the scope of the invention. In addition, many modifications may be made to adapt a particular situation or material to the teachings of the invention without departing from its scope. Therefore, it is intended that the invention not be limited to the particular embodiments disclosed, but that the invention will include all embodiments falling within the scope of the appended claims.

What is claimed is:

1. A method comprising:
dividing one or more scan chains into a number of segments, wherein each of said segments comprises a subset of flip-flops of a scan chain of said one or more scan chains, said dividing used to minimize loading affecting a first control signal, said loading caused by a current drain from said flip-flops of said scan chain of said one or more scan chains; and
adding a first circuitry to each of said number of segments, said first circuitry used to condition said first control signal received by each of said segments, said first circuitry regenerating a second control signal used by each of said flip-flops, such that said second control signal is capable of driving an input of each of said plurality of flip-flops with sufficient current at high frequencies.

2. The method of claim 1 comprising:
positioning said first circuitry within each of said segments such that said second control signal is distributed to each of a plurality of flip-flops using a plurality of conductive paths such that variation in lengths of said conductive paths is minimized.

3. The method of claim 2 wherein said variation is equal to zero.

4. The method of claim 2 wherein said second control signal is used to control selection of a capture mode or a scan-in mode of said one or more flip-flops of said each of said segments, said capture mode used to perform at-speed testing, said scan-in mode used to perform shifting-in of data into said digital integrated circuit chip.

5. The method of claim 1 wherein said high frequencies comprise frequencies greater than 100 Mhz.

6. The method of claim 1 wherein a second circuitry is used for clocking data from a segment of a first scan chain in a first clock domain to a segment of a second scan chain in a second clock domain, said second circuitry comprising a first lockup latch used in a scan-in mode and a second lockup latch used in a capture mode of scan testing of a digital integrated circuit chip.

7. The method of claim 6 wherein a third circuitry is used to generate a control signal that is used to reroute data to a first lockup latch or to a second lockup latch of said second circuitry.

8. The method of claim 1 wherein said first control signal and a clock signal are provided to said first circuitry by way of a fourth circuitry, said fourth circuitry receiving a signal from a phase locked loop (PLL).

9. The method of claim 8 wherein said fourth circuitry is positioned in a location relative to said number of segments such that the variation in conductive path length between said fourth circuitry and said segments is minimized.

10. The method of claim 9 wherein said variation is equal to zero.

11. The method of claim 1 comprising:
first interconnecting at least two segments of said number of segments if said at least two segments operate in the same clock domain; and
second interconnecting two segments using a lock logic circuitry if said two segments operate in different clock domains.

12. The method of claim 11 wherein said lock logic circuitry comprises a first lockup latch used in a scan-in mode and a second lockup latch used in a capture mode of scan testing of a digital integrated circuit chip.

13. A system for scan testing a digital integrated circuit chip comprising:
a first circuitry incorporated into each of a plurality of segments, wherein each of said segments comprises a fraction of flip-flops of a scan chain of one or more scan chains, said first circuitry used to condition a first signal, said first circuitry outputting a second signal capable of driving each flip-flop within said fraction of flip-flops in each of said plurality of segments.

14. The system of claim 13 wherein said first circuitry is positioned within each of said segments such that said second signal is distributed by way of a plurality of conductive paths terminating at said plurality of flip-flops wherein variation in lengths of said plurality of conductive paths is minimized.

15. The system of claim 13 wherein said second signal is used to select a capture mode or a scan-in mode of said fraction of flip-flops, said capture mode used to perform at-speed testing of said one or more scan chains of said digital integrated circuit chip.

16. The system of claim 15 wherein said at-speed testing is performed at frequencies of at least 100 Mhz.

17. The system of claim 13 comprising:
a second circuitry used for clocking data from a segment of a first scan chain in a first clock domain to a segment of a second scan chain in a second clock domain, said second circuitry used to isolate and reroute data during a transition between a scan-in mode to a capture mode of said scan testing.

18. The system of claim 17 wherein said second circuitry comprises two latches and a multiplexer.

19. The system of claim 17 wherein a third circuitry is used to generate a control signal that selectively performs said reroute of data to a first latch or to a second latch of said second circuitry.

20. The system of claim 19 comprising:
a fourth circuitry used for generating a clock signal and said first signal used by said first circuitry, said fourth circuitry receiving a signal from a phase locked loop (PLL).

21. The system of claim 20 wherein said fourth circuitry is positioned in a location on said digital integrated circuit chip such that the variation in conductive path lengths used for transmitting said clock signal and said first signal between said fourth circuitry and each of said plurality of segments is minimized.
